(19) United States
(12) Patent Application Publication
(10) Pub. No.: US 2008/0079174 A1
(43) Pub. Date: Apr. 3, 2008

(54) Substrate slot design for die stack packaging

(76) Inventors: Nelson Punzalan, Kaohisung (TW); Chee Key Chung, Tainan City (TW)

Correspondence Address: INTEL CORPORATION;c/o INTELLEVATE, LLC, P.O. BOX 52050, MINNEAPOLIS, MN, 55402, US

(21) Appl. No.: 11/540,351

(22) Filed: Sep. 29, 2006

(51) Int. Cl. H01L 23/52

(52) U.S. Cl. 257/777

(57) ABSTRACT

In some embodiments, a substrate slot design for die stack packaging is presented. In this regard, an apparatus is introduced having a top integrated circuit die, a bottom integrated circuit die, and a substrate, including a slot through which the bottom integrated circuit die is wirebonded to contacts on a bottom surface of the substrate. Other embodiments are also disclosed and claimed.

### FIELD OF THE INVENTION

Embodiments of the present invention generally relate to the field of integrated circuit packages, and, more particularly to a substrate slot design for die stack packaging.

### BACKGROUND OF THE INVENTION

The demand for enhanced performance and functionality of integrated circuit components continues to increase design and fabrication complexity. An integrated circuit package can have increased flexibility and functionality within the same footprint by stacking multiple dice on top of each other. For example, if there is a need to increase the memory capacity of a package, 2 or more memory dice are stacked on top of each other. However, if the dice to be stacked are of the same dimensions, there is a need to add a spacer between them to allow for wirebonding to the substrate.

### BRIEF DESCRIPTION OF THE DRAWINGS

The present invention is illustrated by way of example and not limitation in the figures of the accompanying drawings in which like references indicate similar elements, and in which:

FIG. 1 is a graphical illustration of a cross-sectional view of a substrate slot design for die stack packaging, in accordance with one example embodiment of the invention;

FIG. 2 is a graphical illustration of a bottom-up view of a slotted substrate, in accordance with one example embodiment of the invention;

FIG. 3 is a graphical illustration of a cross-sectional view of a substrate slot design for die stack packaging, in accordance with one example embodiment of the invention;

FIG. 4 is a graphical illustration of a bottom-up view of a slotted substrate, in accordance with one example embodiment of the invention; and

FIG. 5 is a block diagram of an example electronic appliance suitable for implementing a substrate slot design for die stack packaging, in accordance with one example embodiment of the invention.

### DETAILED DESCRIPTION

In the following description, for purposes of explanation, numerous specific details are set forth in order to provide a thorough understanding of the invention. It will be apparent, however, to one skilled in the art that embodiments of the invention can be practiced without these specific details. In other instances, structures and devices are shown in block diagram form in order to avoid obscuring the invention.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

FIG. 1 is a graphical illustration of a cross-sectional view of a substrate slot design for die stack packaging, in accordance with one example embodiment of the invention. In accordance with the illustrated example embodiment, package 100 includes one or more of substrate 102, bottom die 104, adhesive 106, top die 108, adhesive 110, wire 112, top substrate surface 114, slot 116, bottom substrate surface 118, mold 120 and solder ball 122.

Substrate 102 represents a substrate that may comprise multiple conductive layers laminated together. Substrate 102 may be laminated with dielectric material as part of a substrate build-up and may have insulated traces and vias routed through it.

Bottom die 104 represents an integrated circuit die. In one embodiment, bottom die 104 represents a memory device. In another embodiment, bottom die 104 represents a logic device. Bottom die 104 is mechanically attached to substrate 102 by adhesive 106, which represents a thin-film attachment material. Top die 108 is mechanically attached to bottom die 104 by adhesive 110. In one embodiment, top die 108 is the same type of device as bottom die 104. In another embodiment, top die 108 is a different type of device than bottom die 104.

Wire 112 represents wirebonding that electrically couples top die 108 to contacts on top substrate surface 114.

Slot 116 in substrate 102 provides an opening through which bond pads near a center of bottom die 104 are wirebonded to contacts on bottom substrate surface 118. In one embodiment, slot 116 is created in substrate 102 by laser routing and/or mechanical punching. One skilled in the art would recognize that by wirebonding die 104 to substrate 102 through slot 116, that die 108 is able to be placed directly on die 104 without the need for a spacer. Additionally by utilizing both top substrate surface 114 and bottom substrate surface 118 for wirebonding, it is possible to better manage traces and electrical performance. In one embodiment, slot 116 is encapsulated, for example with an epoxy resin compound, to protect the wires and contacts from damage.

Mold 120 is used to protect dies 104 and 108 as well as wire 112. In one embodiment, mold 120 is an epoxy resin compound.

Solder ball 122 may be added to package 100 to allow package 100 to be coupled, for example to a substrate or printed circuit board. Other electrical interfaces besides solder balls may also be utilized.

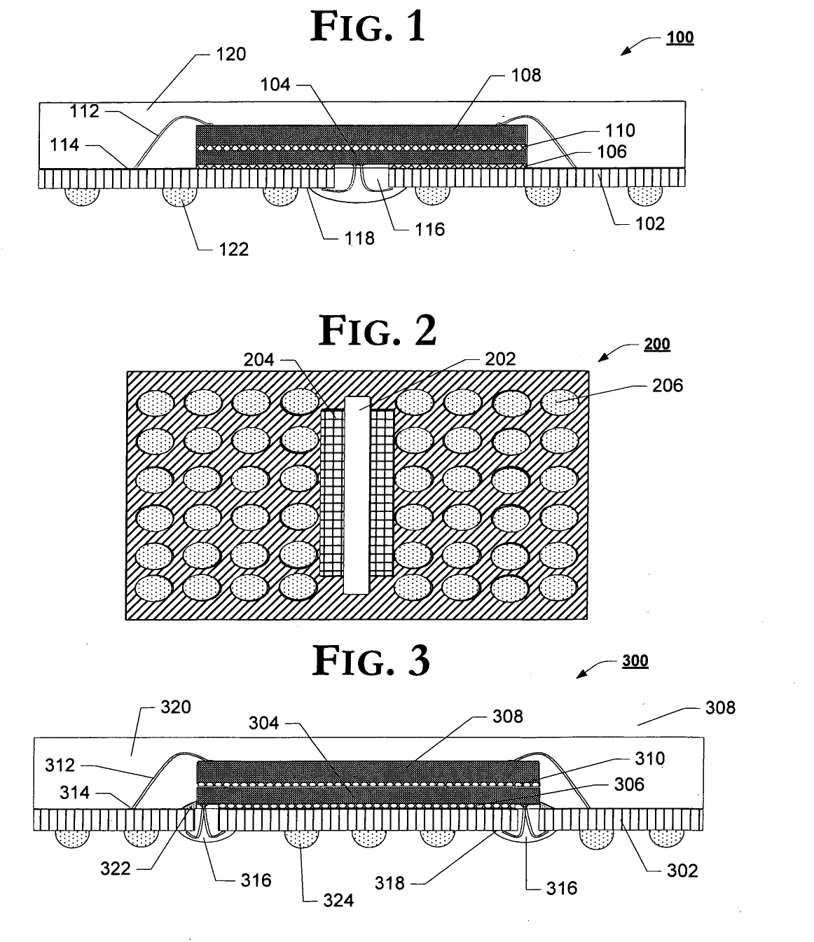

FIG. 2 is a graphical illustration of a bottom-up view of a slotted substrate, in accordance with one example embodiment of the invention. As shown, substrate 200, includes one or more of slot 202, leadfinger 204 and ball pad 206.

Slot 202 is used to access bond pads near a center of a die attached to the opposite side of substrate 200. In one embodiment, wirebonding is utilized to electrically couple the bond pads with leadfinger 204.

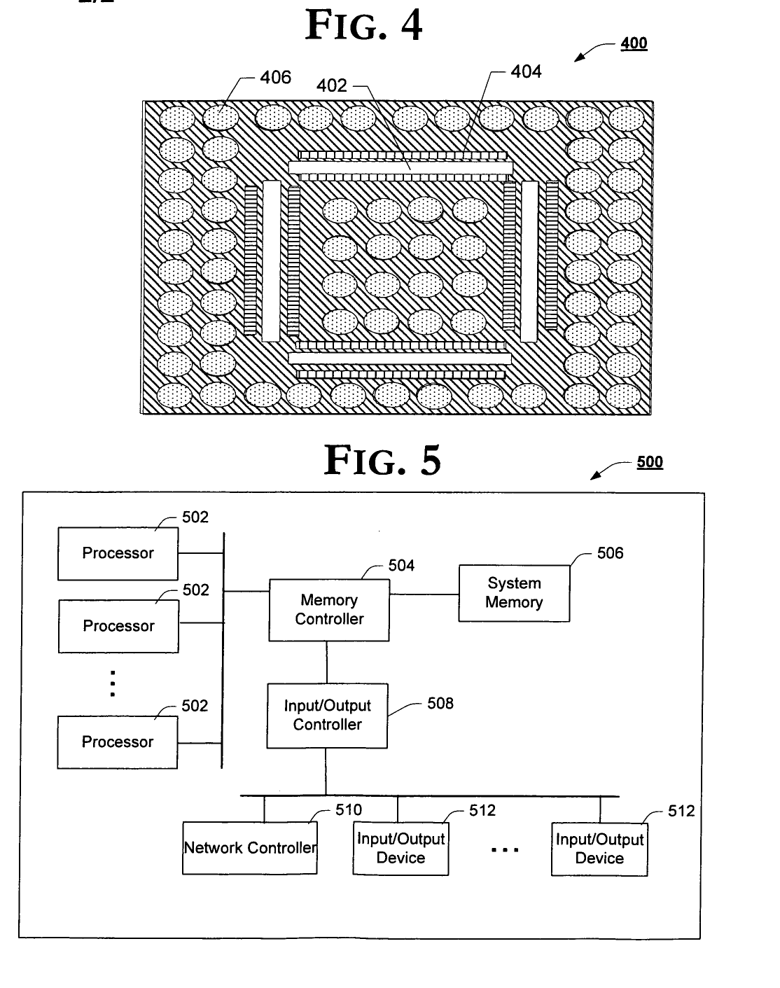

FIG. 3 is a graphical illustration of a cross-sectional view of a substrate slot design for die stack packaging, in accordance with one example embodiment of the invention. As shown, package 300 includes one or more of substrate 302, bottom die 304, adhesive 306, top die 308, adhesive 310, wire 312, top substrate surface 314, slot 316, bottom substrate surface 318, mold 320, edge sealant 322 and solder ball 324.

Substrate 302 includes slot 316 that represent multiple throughholes to allow wirebonding of bond pads located near edges of bottom die 304 to contacts on bottom substrate surface 318. In one embodiment, to prevent mold 320 from seeping into slot 316, edge sealant 322 is added to top substrate surface 314. In one embodiment, edge sealant 322 is a quick-drying, low-viscosity sealant.

FIG. 4 is a graphical illustration of a bottom-up view of a slotted substrate, in accordance with one example embodiment of the invention. As shown, substrate 400 includes one or more of slot 402, leadfinger 404 and ball pad 406.

Slot 402 is used to access bond pads near an edge of a die attached to the opposite side of substrate 400. In one embodiment, wirebonding is utilized to electrically couple the bond pads with leadfinger 404. Slot 402 may be of any shape and size and may comprise a plurality of throughholes.

FIG. 5 is a block diagram of an example electronic appliance suitable for implementing a substrate slot design for die stack packaging, in accordance with one example embodiment of the invention. Electronic appliance 500 is intended to represent any of a wide variety of traditional and non-traditional electronic appliances, laptops, desktops, cell phones, wireless communication subscriber units, wireless communication telephony infrastructure elements, personal digital assistants, set-top boxes, or any electric appliance that would benefit from the teachings of the present invention. In accordance with the illustrated example embodiment, electronic appliance 500 may include one or more of processor(s) 502, memory controller 504, system memory 506, input/output controller 508, network controller 510, and input/output device(s) 512 coupled as shown in FIG. 5. Processor(s) 502, or other integrated circuit components of electronic appliance 500, may be housed in a package including a slotted substrate described previously as an embodiment of the present invention.

Processor(s) 502 may represent any of a wide variety of control logic including, but not limited to one or more of a microprocessor, a programmable logic device (PLD), programmable logic array (PLA), application specific integrated circuit (ASIC), a microcontroller, and the like, although the present invention is not limited in this respect. In one embodiment, processors(s) 502 are Intel® compatible processors. Processor(s) 502 may have an instruction set containing a plurality of machine level instructions that may be invoked, for example by an application or operating system.

Memory controller 504 may represent any type of chipset or control logic that interfaces system memory 508 with the other components of electronic appliance 500. In one embodiment, the connection between processor(s) 502 and memory controller 504 may be referred to as a front-side bus. In another embodiment, memory controller 504 may be referred to as a north bridge.

System memory 506 may represent any type of memory device(s) used to store data and instructions that may have been or will be used by processor(s) 502. Typically, though the invention is not limited in this respect, system memory 506 will consist of dynamic random access memory (DRAM). In one embodiment, system memory 506 may consist of Rambus DRAM (RDRAM). In another embodiment, system memory 506 may consist of double data rate synchronous DRAM (DDRSDRAM).

Input/output (I/O) controller 508 may represent any type of chipset or control logic that interfaces I/O device(s) 512 with the other components of electronic appliance 500. In one embodiment, I/O controller 508 may be referred to as a south bridge. In another embodiment, I/O controller 508 may comply with the Peripheral Component Interconnect (PCI) Express™ Base Specification, Revision 1.0a, PCI Special Interest Group, released Apr. 15, 2003.

Network controller 510 may represent any type of device that allows electronic appliance 500 to communicate with other electronic appliances or devices. In one embodiment, network controller 510 may comply with a The Institute of Electrical and Electronics Engineers, Inc. (IEEE) 802.11b standard (approved Sep. 16, 1999, supplement to ANSI/IEEE Std 802.11, 1999 Edition). In another embodiment, network controller 510 may be an Ethernet network interface card.

Input/output (I/O) device(s) 512 may represent any type of device, peripheral or component that provides input to or processes output from electronic appliance 500.

In the description above, for the purposes of explanation, numerous specific details are set forth in order to provide a thorough understanding of the present invention. It will be apparent, however, to one skilled in the art that the present invention may be practiced without some of these specific details. In other instances, well-known structures and devices are shown in block diagram form.

Many of the methods are described in their most basic form but operations can be added to or deleted from any of the methods and information can be added or subtracted from any of the described messages without departing from the basic scope of the present invention. Any number of variations of the inventive concept is anticipated within the scope and spirit of the present invention. In this regard, the particular illustrated example embodiments are not provided to limit the invention but merely to illustrate it. Thus, the scope of the present invention is not to be determined by the specific examples provided above but only by the plain language of the following claims.

What is claimed is:

1. An apparatus comprising:
a top integrated circuit die;
a bottom integrated circuit die; and
a substrate, including a slot through which the bottom integrated circuit die is wirebonded to contacts on a bottom surface of the substrate.

2. The apparatus of claim 1, wherein the top integrated circuit die is stacked on the bottom integrated circuit die.

3. The apparatus of claim 2, wherein the top and bottom integrated circuit dice are substantially the same size.

4. The apparatus of claim 2, further comprising encapsulant covering the slot.

5. The apparatus of claim 2, further comprising leadfingers on the bottom of the substrate coupled with bonding wires.

6. The apparatus of claim 2, further comprising solder balls on the bottom of the substrate.

7. The apparatus of claim 1, wherein the bottom integrated circuit die comprises a center bond pad.

8. The apparatus of claim 1, wherein the bottom integrated circuit die comprises an edge bond pad.

9. An electronic appliance comprising:
a network controller;
a system memory; and
a processor, wherein the processor includes two or more stacked dice and a slotted substrate, wherein a die attached to a top surface of the substrate is wirebonded through the slot to a bottom surface of the substrate.

10. The electronic appliance of claim 9, wherein at least two stacked dice are substantially the same size.

11. The electronic appliance of claim 9, further comprising encapsulant filling the slot.

12. The electronic appliance of claim 9, further comprising leadfingers on the bottom surface of the substrate to receive the wirebonding.

13. The electronic appliance of claim 9, further comprising solder balls on the bottom surface of the substrate.

14. The electronic appliance of claim 9, wherein the slot is substantially in a center of the substrate.

15. The electronic appliance of claim 9, wherein the slot comprises multiple throughholes.

16. A method comprising:
stacking a second die on top of a first die; and
wirebonding the first die to a bottom of a substrate through a slot in the substrate.

17. The method of claim 16, wherein the first die comprises a bond pad near an edge.

18. The method of claim 16, wherein the first die comprises a bond pad near a center.

19. The method of claim 16, further comprising:
wirebonding the second die to a top of the substrate; and
molding the top of the substrate including the stacked dice.

20. The method of claim 16, further comprising encapsulating the slot in the substrate.
